(19) United States
(12) Patent Application Publication
(10) Pub. No.: US 2007/0082498 A1
(43) Pub. Date: Apr. 12, 2007

(54) METHOD OF CLEANING A WAFER

(76) Inventors: Chien-Hsun Chen, Hsin-Chu City (TW); Kuang-Hua Shih, Hsin-Chu City (TW); Sheng-Jie Hsu, Tai-Chung Hsien (TW); Jung-Wei Huang, Chi-Lung City (TW)

Correspondence Address: NORTH AMERICA INTELLECTUAL PROPERTY CORPORATION, P.O. BOX 506, MERRIFIELD, VA, 22116, US

(21) Appl. No.: 11/163,157

(22) Filed: Oct. 7, 2005

(51) Int. Cl. H01L 21/302; H01L 21/44

(52) U.S. Cl. 438/754; 438/664; 438/755; 438/677

(57) ABSTRACT

A wafer having a metal layer inclding salicide regions and unreacted metal regions disposed thereon is provided. Subsequently, an acidic solution is provided to remove the unreacted metal regions. Following that, a cold APM solution is used to remove particles subsequent to using the acidic solution to remove the unreacted metal regions. Finally, a mega sonic energy is applied to the wafer together with the cold APM solution or separately.

### BACKGROUND OF THE INVENTION

1. Field of the Invention

The present invention pertains to a method of cleaning a wafer, and more particularly, to a method of cleaning a wafer using a cold APM solution and/or a mega sonic energy subsequent to a salicidation process.

2. Description of the Prior Art

The purity of wafer is essential to the reliability of semiconductor devices. Among various semiconductor processes, such as deposition process, photolithography process, etching process, CMP process, etc, appearance of particles may result from reaction by-products, residues in reaction chambers, and impurities in clean room. Once particles appear and are not removed, the yield of successive processes will be seriously influenced. Therefore, clean process has to be performed frequently to ensure the purity of wafer.

Please refer to FIG. 1. FIG. 1 is a flow chart illustrating a conventional method of cleaning a wafer subsequent to a salicidation process. As shown in FIG. 1, the steps of cleaning a wafer in accordance with the conventional method are listed as follows.

Step 10: start;

Step 12: provide a wafer having a metal layer including salicide regions and unreacted metal regions disposed thereon;

Step 14: use an SPM (sulfuric peroxide mixture) solution to remove the unreacted metal regions;

Step 16: use a hot APM (ammonium peroxide mixture) solution to remove particles; and

Step 18: end.

Please continue referring to FIG. 2 through FIG. 5. FIG. 2 through FIG. 5 are schematic diagrams illustrating the conventional method of cleaning a wafer subsequent to a salicidation process, in which only a MOS transistor is illustrated. As shown in FIG. 2, a wafer 20 is provided. Then, a MOS transistor including a gate dielectric layer 22 disposed on the wafer 20, a gate 24 made of polycrystalline silicon disposed on the gate dielectric layer 22, spacers 26 disposed alongside the gate 24, source/drain regions 28 positioned in the wafer 20, and STIs 30 is formed.

As shown in FIG. 3, a metal layer 32 is deposited on the wafer 20, and a thermal process, e.g. an RPT process, is performed to react the metal layer 32 with the gate 24 and the source/drain regions 28. Consequently, Salicide regions 34 are formed in the upper portion of the gate 24 and the source/drain regions 28, while unreacted metal regions 36 remain on the spacers 26 and the STIs 30.

As shown in FIG. 4, an SPM solution that contains sulfuric acid and hydrogen peroxide is used to remove the unreacted metal regions (not shown) disposed on the spacers 26 and the STIs 30. While the SPM solution removes the unreacted metal regions, particles 38 also appear on the surface of the wafer 20. As shown in FIG. 5, a hot APM solution that contains ammonium and hydrogen peroxide is used to remove particles 38 generated while removing the unreacted metal regions (not shown). In accordance with the prior art method, the temperature of the hot APM solution is higher than 70° C. The hot APM solution at such a high temperature will corrupt the salicide regions 34, and therefore a portion of the salicide regions 34 are removed as well as the particles 38. Consequently, the resistance of the salicide regions 34 is increased.

In accordance with another conventional method, the hot APM solution is applied first to clean the wafer, and the SPM solution is used subsequent to the hot APM solution to remove the unreacted metal regions. However, particles generated while removing the unreacted metal regions are not removed, and this leads to photoresist collapse in successive lithography process of defining contact holes. Therefore, an improved method of cleaning a wafer capable of effectively removing particles without damaging the salicide regions is required.

### SUMMARY OF THE INVENTION

It is therefore one object of the claimed invention to provide a method of cleaning a wafer to overcome the aforementioned problems.

To achieve the above object, a method of cleaning a wafer is provided. First, a wafer having a metal layer disposed thereon is provided. Subsequently, an acidic solution is used to clean the wafer. Finally, a cold APM solution is used to clean the wafer.

To achieve the above object, another method of cleaning a wafer is provided. First, a wafer having a metal layer disposed thereon is provided. Then, an acidic solution is used to clean the wafer. Following that, a mega sonic energy is applied to clean the wafer.

To achieve the above object, still another method of cleaning a wafer is provided. A wafer having a metal layer including salicide regions and unreacted metal regions disposed thereon is provided. Subsequently, an acidic solution is provided to remove the unreacted metal regions. Following that, a cold APM solution is used to remove particles subsequent to using the acidic solution to remove the unreacted metal regions. Finally, a mega sonic energy is applied to the wafer together with the cold APM solution or separately.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a flow chart illustrating a conventional method of cleaning a wafer subsequent to a salicidation process.

FIG. 2 through FIG. 5 are schematic diagrams illustrating the conventional method of cleaning a wafer subsequent to a salicidation process.

FIG. 6 is a flow chart illustrating a method of cleaning a wafer in accordance with a first preferred embodiment of the present invention.

FIG. 7 is a flow chart illustrating a method of cleaning a wafer in accordance with a second preferred embodiment of the present invention.

FIG. 8 is a flow chart illustrating a method of cleaning a wafer in accordance with a third preferred embodiment of the present invention.

FIG. 9 through FIG. 12 are schematic diagrams illustrating the method of cleaning a wafer according to the present invention.

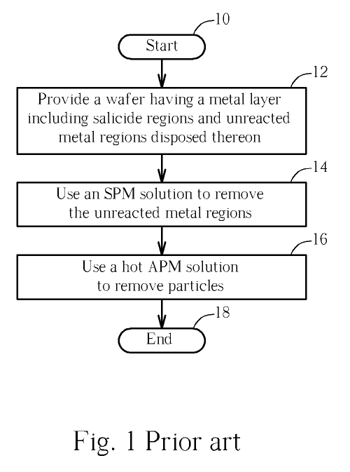

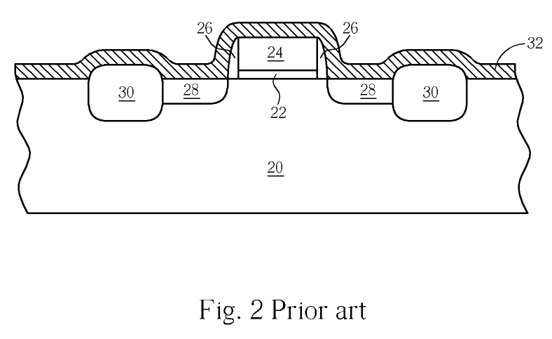

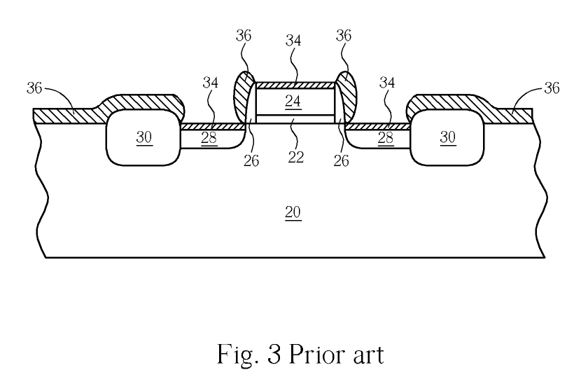

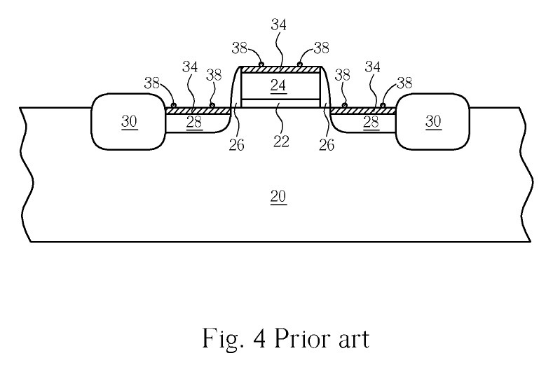

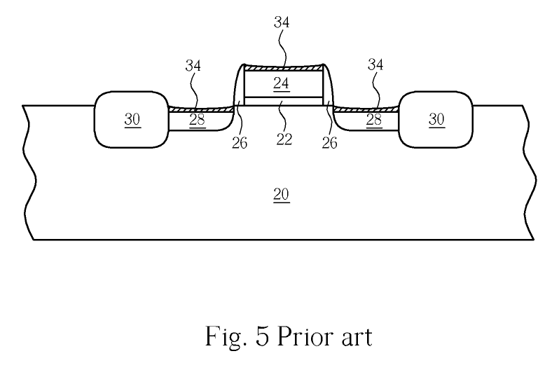

### DETAILED DESCRIPTION

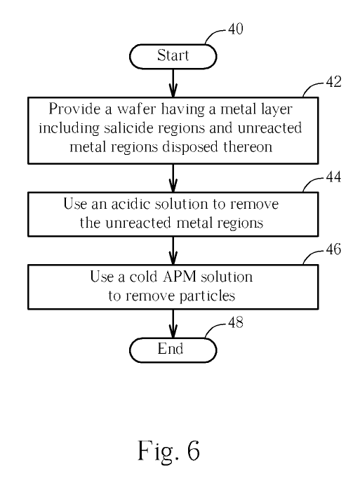

Please refer to FIG. 6. FIG. 6 is a flow chart illustrating a method of cleaning a wafer in accordance with a first preferred embodiment of the present invention. As shown in FIG. 6, the steps of cleaning a wafer in accordance with the present invention are listed as follows.

Step 40: start;

Step 42: provide a wafer having a metal layer including salicide regions and unreacted metal regions disposed thereon;

Step 44: use an acidic solution to remove the unreacted metal regions;

Step 46: use a cold APM solution to remove particles; and

Step 48: end.

In accordance with the first preferred embodiment of the present invention, the wafer has been treated with a salicidation process, and thus has salicide regions formed in the upper portion of silicon-based regions e.g. gate and source/drain regions. Meanwhile, the metal layer that does not react with the wafer (silicon) forms unreacted metal regions remaining on the wafer. Therefore, an acidic solution is adopted to remove the unreacted metal regions. In this embodiment, the acidic solution is an SPM solution that contains sulfuric acid, hydrogen peroxide, and water, and the mixing ratio may be modified. After the unreacted metal regions are removed, a cold APM solution (also referred to as RCA SC1 solution) that contains ammonium, hydrogen peroxide and water is selected to clean particles generated in the step of removing the unreacted metal regions. It is appreciated that the temperature of the APM solution is kept between 10 to 60° C. (preferably between 20 to 40° C.) so that the APM solution does not attack the salicide regions while removing the particles. In addition, the wafer may be further dipped into DI water or rinsed by DI water to ensure the purity of wafer.

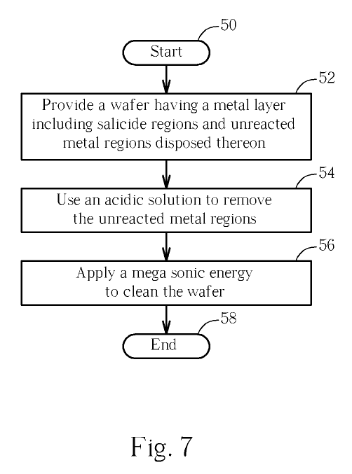

Please refer to FIG. 7. FIG. 7 is a flow chart illustrating a method of cleaning a wafer in accordance with a second preferred embodiment of the present invention. As shown in FIG. 7, the steps of cleaning a wafer in accordance with the present invention are listed as follows.

Step 50: start;

Step 52: provide a wafer having a metal layer including salicide regions and unreacted metal regions disposed thereon;

Step 54: use an acidic solution to remove the unreacted metal regions;

Step 56: apply a mega sonic energy to clean the wafer; and

Step 58: end.

In accordance with the second preferred embodiment of the present invention, the wafer is cleaned by applying a mega sonic energy. Similar to the first preferred embodiment, the wafer has salicide regions formed in the upper portion of silicon-based regions e.g. gate and source/drain regions, and the metal layer that does not react with the wafer (silicon) forms unreacted metal regions on the wafer. Therefore, an SPM solution that contains sulfuric acid, hydrogen peroxide and water is used to remove the unreacted metal regions first. Subsequently, the wafer is dipped into DI water and a mega sonic energy is applied to remove particles adhered to the wafer. In this embodiment, the mega sonic energy is set between 50 and 600 watts (preferably 100 watts), and the frequency range may be modified. By virtue of vibrations, the particles adhered to the wafer therefore fall off, and the purity of wafer is ensured.

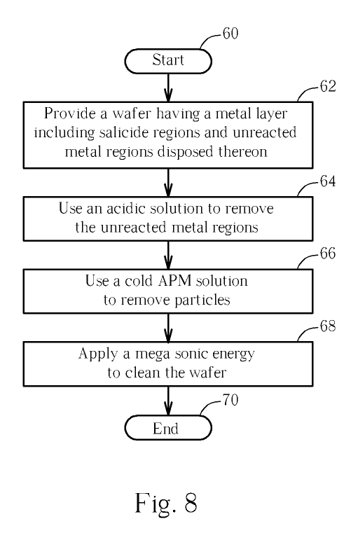

Please refer to FIG. 8. FIG. 8 is a flow chart illustrating a method of cleaning a wafer in accordance with a third preferred embodiment of the present invention. As shown in FIG. 8, the steps of cleaning a wafer in accordance with the present invention are listed as follows.

Step 60: start;

Step 62: provide a wafer having a metal layer including salicide regions and unreacted metal regions disposed thereon;

Step 64: use an acidic solution to remove the unreacted metal regions;

Step 66: use a cold APM solution to remove particles

Step 68: apply a mega sonic energy to clean the wafer; and

Step 70: end.

In the third embodiment, both the cold APM solution and mega sonic energy are adopted to improve particle-removing effect. Therefore, after the unreacted metal regions are removed. First, a cold APM solution that contains ammonium, hydrogen peroxide and water is used to clean particles generated in the step of removing the unreacted metal regions. Subsequently, a mega sonic energy having a power range between 50 to 600 watts (preferably 100 watts) is applied to further remove particles adhered to the wafer. In this embodiment, the temperature of the APM solution is kept between 10 to 60° C. (preferably between 20 to 40° C.) so that the APM solution does not attack the salicide regions while removing the particles. It is appreciated that the mega sonic energy is applied while the wafer is cleaned by the cold APM solution. In other words, these two clean steps are carried out simultaneously. However, these two steps may also be implemented separately. For example, the mega sonic energy may be applied in a DI water tank after the wafer is cleaned by the cold APM solution, or vise versa. In addition, the wafer may be further dipped into DI water or rinsed by DI water or some other clean solutions to ensure the purity of wafer prior to or subsequent to these two clean steps.

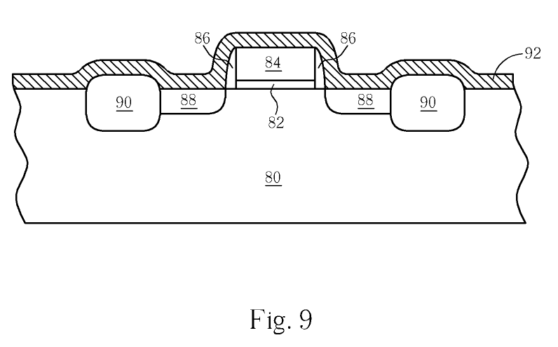

Please refer to FIG. 9 through FIG. 12. FIG. 9 through FIG. 12 are schematic diagrams illustrating the method of cleaning a wafer according to the present invention, in which only a MOS transistor is illustrated. As shown in FIG. 9, a wafer 80 is provided. A MOS transistor including a gate dielectric layer 82 disposed on the wafer 80, a gate 84 made of polycrystalline silicon disposed on the gate dielectric layer 82, spacers 86 positioned alongside the gate 84, source/drain regions 88 disposed in the wafer 80, and STIs 90 is formed.

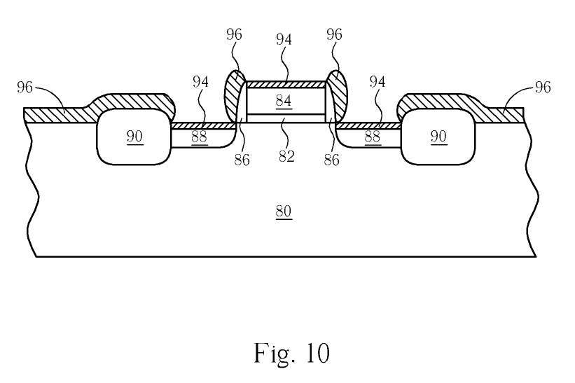

As shown in FIG. 10, a metal layer 92, e.g. a cobalt layer, a nickel layer or a titanium layer, is deposited on the wafer 80, and a thermal process, e.g. an RPT process, is performed to react the metal layer 92 with the gate 84 and the source/drain regions 88. Consequently, Salicide regions 94 are formed in the upper portion of the gate 84 and the source/drain regions 88, while unreacted metal regions 96 remain on the spacers 86 and the STIs 90.

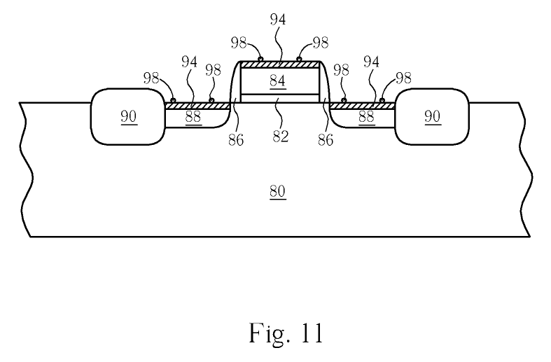

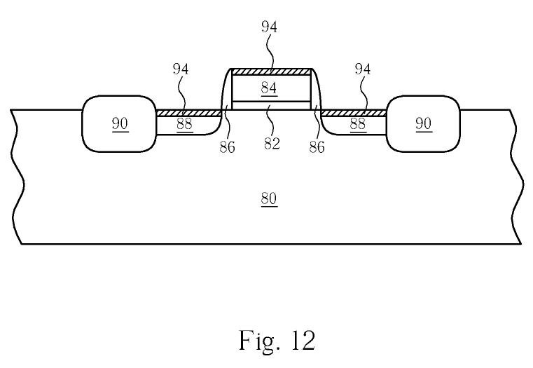

As shown in FIG. 11, an SPM solution that contains sulfuric acid and hydrogen peroxide is used to remove the unreacted metal regions (not shown) disposed on the spacers 86 and the STIs 90. As described, particles 98 may appear after removing the unreacted metal regions 96, and adhere to the wafer 80. As shown in FIG. 12, the cold APM solution and/or the mega sonic energy are used here to remove particles 98. Since both of these clean steps are able to remove the particles 98 without damaging the salicide regions 94, the thickness and resistance of the salicide regions 94 are not influenced after the clean process.

It is appreciated that the method of cleaning a wafer is illustrated while performed after a salicidation process in the aforementioned embodiments, however, the application of the present invention is not limited and may also be applied to remove particles after other process whenever necessary. In addition, the unreacted metal regions to be removed may be made of different metals. The acidic solution used to remove the metal regions is not limited to SPM solution, and may contain phosphoric acid, fluoric acid, etc. The ratio of the cold APM solution may also be modified if different metals are to be removed. Furthermore, conventional clean steps may also be adopted in combination with the method of the present invention to enhance cleaning and particle-removing effect. For example, other clean solutions or DI water may be used to rinse the wafer, or the wafer can be brushed during the clean step.

In conclusion, the method of clean a wafer according to the present invention utilizes a cold APM solution and/or a mega sonic energy to remove particles without damaging the salicide regions. Consequently, the resistance of the salicide regions is ensured. In addition, the yield of successive processes e.g. lithography process and contact holes is improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of cleaning a wafer, comprising:
providing a wafer having a metal layer disposed thereon;
using an acidic solution to clean the wafer; and
using a cold APM (ammonium peroxide mixture) solution to clean the wafer.

2. The method of claim 1, wherein the cold APM solution having a temperature range between 10 and 60° C.

3. The method of claim 1, wherein a mega sonic energy is applied while using the cold APM solution to clean the wafer.

4. The method of claim 3, wherein the mega sonic energy has a power range between 50 and 600 watts.

5. The method of claim 1, wherein the acidic solution comprises an SPM (sulfuric peroxide mixture) solution.

6. The method of claim 1, wherein the metal layer comprises salicide regions and unreacted metal regions, the acidic solution is used to remove the unreacted metal regions, and the cold APM solution is used to remove particles.

7. A method of cleaning a wafer, comprising:
providing a wafer having a metal layer disposed thereon;
using an acidic solution to clean the wafer; and
applying a mega sonic energy to clean the wafer.

8. The method of claim 7, wherein the mega sonic energy has a power range between 50 to 600 watts.

9. The method of claim 7, wherein the mega sonic energy is applied while the wafer is dipped into DI wafer.

10. The method of claim 7, further comprising using a cold APM (ammonium peroxide mixture) solution to clean the wafer subsequent to using the acidic solution to clean the wafer.

11. The method of claim 10, wherein the cold APM solution having a temperature range between 10 and 60° C.

12. The method of claim 10, wherein the mega sonic energy is applied while using the cold APM solution to clean the wafer.

13. The method of claim 7, wherein the acidic solution comprises an SPM (sulfuric peroxide mixture) solution.

14. The method of claim 13, wherein the metal layer comprises salicide regions and unreacted metal regions, the acidic solution is used to remove the unreacted metal regions, and the cold APM solution is used to remove particles.

15. A method of cleaning a wafer, comprising:
providing a wafer having a metal layer comprising salicide regions and unreacted metal regions disposed thereon;
using an acidic solution to remove the unreacted metal regions;
using a cold APM (ammonium peroxide mixture) solution, subsequent to using the acidic solution to remove the unreacted metal regions, to remove particles; and
applying a mega sonic energy to the wafer.

16. The method of claim 15, wherein the mega sonic energy is applied to the wafer while using the cold APM solution to clean the wafer.

17. The method of claim 15, wherein the mega sonic energy is applied while the wafer is dipped into DI water.

18. The method of claim 15, wherein the cold APM solution having a temperature range between 10 and 60° C.

19. The method of claim 15, wherein the mega sonic energy has a power range between 50 to 600 watts.
